(19) United States
(12) Patent Application Publication
(10) Pub. No.: US 2019/0044005 A1
(43) Pub. Date: Feb. 7, 2019

(54) CONDUCTIVE PASTE AND SOLAR CELL

(71) Applicant: NAMICS CORPORATION, Niigata-shi, Niigata (JP)

(72) Inventor: Kenichi SAKATA, Niigata-shi, Niigata (JP)

(73) Assignee: NAMICS CORPORATION, Niigata-shi, Niigata (JP)

(21) Appl. No.: 16/074,883

(22) PCT Filed: Feb. 24, 2017
(86) PCT No.: PCT/JP2017/006994

§ 371 Date: Aug. 2, 2018

(30) Foreign Application Priority Data
Mar. 9, 2016 (JP) 2016-045238

(51) Int. Cl. H01L 31/0224; H01B 1/22; H01L 21/28; H01L 23/482; H01L 31/0216; H01L 31/036

(52) U.S. Cl. CPC H01L 31/022425; H01B 1/22; H01L 31/036; H01L 23/4828; H01L 31/02167; H01L 21/28

(57) ABSTRACT

An electrically conductive paste used to form an electrode used for electrical connection to a p-type semiconductor layer of a crystalline silicon solar cell, wherein the electrically conductive paste is able to fire through an antireflective film during firing and is capable of forming an electrode having low contact resistance on a p-type semiconductor layer. The electrically conductive paste contains (A) an electrically conductive powder, (B) Al powder or Al compound powder having an average particle diameter of 0.5 μm to 3.5 μm, (C) a glass frit and (D) an organic medium, and contains 0.5 parts by weight to 5 parts by weight of the Al powder or Al compound powder (B) based on 100 parts by weight of the electrically conductive powder (A).

### TECHNICAL HELD

The present invention relates to an electrically conductive paste used to form an electrode of a semiconductor device and the like. More particularly, the present invention relates to an electrically conductive paste for forming an electrode of a solar cell. In addition, the present invention relates to a solar cell produced using an electrically conductive paste for forming an electrode thereof.

### BACKGROUND ART

Semiconductor devices such as crystalline silicon solar cells, which use crystalline silicon obtained by processing single crystalline silicon or polycrystalline silicon into the shape of a sheet, for the substrate thereof typically form electrodes on the surface of the silicon substrate by using an electrically conductive paste for electrode formation. Among these semiconductor devices having an electrode formed in this manner, the production volume of crystalline silicon solar cells has increased considerably in recent years. These solar cells have an impurity diffusion layer, antireflective film and light incident side electrode on one of the surfaces of the crystalline silicon substrate and have a back side electrode on the other surface. Electrical power generated by the crystalline silicon solar cell can be extracted by the light incident side electrode and the back side electrode.

An electrically conductive paste containing electrically conductive powder, glass frit, organic binder, solvent and other additives has been used to form the electrodes of conventional crystalline silicon solar cells. Silver particles (silver powder) are mainly used for the electrically conductive powder.

An example of the electrically conductive paste used to form the electrodes of solar cells is described in Patent Document 1 as an electrically conductive paste containing (i) 100 parts of an electrically conductive powder containing a metal selected from the group consisting of silver, nickel, copper and a mixture thereof, (ii) 0.3 parts by weight to 0.8 parts by weight of an aluminum powder having a particle diameter of 3 μm to 11 μm, (iii) 3 parts by weight to 22 parts by weight of glass frit, and (iv) an organic medium.

In addition, Patent Document 2 describes an Ag—Al paste for p-type semiconductor and an Ag—Al paste for an n-type semiconductor that are used to form the electrodes of a bifacial solar cell.

### PATENT DOCUMENTS

Patent Document 1: JP 2014-515161 A
Patent Document 2: JP 2014-192262 A

### DISCLOSURE OF THE INVENTION

### Problems to be Solved by the Invention

FIG. 1 shows an example of a cross-sectional schematic diagram of a typical crystalline silicon solar cell. As shown in FIG. 1, in this crystalline silicon solar cell, an impurity diffusion layer 4 (such as an n-type impurity diffusion layer having n-type impurities diffused therein) is typically formed on the surface on the light incident side (light incident side surface) of a crystalline silicon substrate 1 (such as a p-type crystalline silicon substrate). An antireflective film 2 is formed on the impurity diffusion layer 4. Moreover, an electrode pattern of light incident side electrodes 20 (surface electrodes) is printed on the antireflective film 2 using an electrically conductive paste by a method such as screen printing, and the light incident side electrodes 20 are formed by drying and firing the electrically conductive paste. During this firing, the light incident side electrodes 20 can be formed so as to contact the impurity diffusion layer 4 as a result of the electrically conductive paste firing through the antireflective film 2. Furthermore, fire-through refers to etching an insulating film in the form of the antireflective film 2 with glass frit and the like contained in the electrically conductive paste to electrically connect the light incident side electrodes 20 and the impurity diffusion layer 4. A back side electrode 15 is typically formed nearly over the entire surface because it is not necessary that light enters from the back side of the p-type crystalline silicon substrate 1. A p-n junction is formed at the interface between the p-type crystalline silicon substrate 1 and the impurity diffusion layer 4. The majority of incident light that has entered the crystalline silicon solar cell passes through the antireflective film 2 and the impurity diffusion layer 4, enters the p-type crystalline silicon substrate 1, and is absorbed during this process thereby generating electron-hole pairs. These electron-hole pairs are such that electrons are separated to the light incident side electrodes 20 and holes are separated to the back side electrode 15 by an electric field attributable to the p-n junction. The electrons and holes (carriers) are extracted to the outside as current via these electrodes.

FIG. 2 shows a schematic diagram of a light incident side surface of an ordinary crystalline silicon solar cell. As shown in FIG. 2, bus bar electrodes (light incident side bus bar electrodes 20a) and finger electrodes 20b are arranged as light incident side electrodes 20 on the light incident side surface of the crystalline silicon solar cell. In the examples shown in FIGS. 1 and 2, carriers generated by incident light that has entered the crystalline silicon solar cell are gathered in the finger electrodes 20b and further gathered in the light incident sided bus bar electrodes 20a. An interconnect metal ribbon or wire, the periphery of which is covered with solder, is soldered to the light incident side bus bar electrodes 20a. Electric current is extracted to the outside by the interconnect metal ribbon or wire.

In general, a p-type impurity diffusion layer 1 has conventionally been used as a crystalline silicon solar cell substrate 1, and an n-type impurity diffusion layer 4 has conventionally been formed on the light incident side surface for the impurity diffusion layer 4. On the other hand, a p-type impurity diffusion layer 4 can also be formed using an n-type crystalline silicon substrate 1. A majority carrier of the n-type crystalline silicon substrate 1 is an electron, and the mobility of the electrons is greater than that of the holes. Consequently, the use of the n-type crystalline silicon substrate 1 can be expected to allow the realization of a solar cell demonstrating higher efficiency.

FIG. 3 shows an example of a schematic diagram of a bifacial solar cell having an electron pattern similar to the light incident side surface on the surface arranged on the back side as well. Furthermore, a bifacial solar cells as referred to here is not necessarily required to have a structure that receives light on both side when formed into a module, but rather may receive light only on one side. In the case the crystalline silicon substrate 1 is of the p-type, the n-type impurity diffusion layer 4 is formed on the main light incident side surface, while a p-type impurity diffusion layer 16 is formed on the back side. In the case the crystalline silicon substrate 1 is of the n-type, the p-type impurity diffusion layer 4 is formed on the main light incident side surface, while an n-type impurity diffusion layer 16 is formed on the back side. Furthermore, the “main light incident side surface” refers to the surface of a bifacial crystalline silicon solar cell on which the p-n junction has been formed. In the present description, the “main light incident side surface” may simply refer to the “light incident side surface”. In addition, the surface on the opposite side from the “Main light incident side surface” is referred to as the “back side”.

In the case of producing a crystalline silicon solar cell using the n-type crystalline silicon substrate 1, an electrically conductive paste for forming the electrode 20 that is electrically connected with the p-type impurity diffusion layer 4 is required to be able to fire through the antireflective film 2 during firing and demonstrate performance that enables electrical contact with the p-type impurity diffusion layer 4 at low contact resistance.

Therefore, an object of the present invention is to provide an electrically conductive paste for forming an electrode used to electrically connect a p-type semiconductor layer of a crystalline silicon solar cell, wherein the electrically conductive paste is able to fire through an antireflective film during firing and is able to form an electrode on the p-type semiconductor layer having low contact resistance.

In addition, an object of the present invention is to provide a high-performance crystalline silicon solar cell having an electrode having low contact resistance on a p-type semiconductor layer.

### Means for Solving the Problems

When an electrically conductive paste containing an Al powder or Al compound powder having a prescribed particle diameter is printed onto a crystalline silicon substrate and fired, an Ag/Al phase is formed and a portion of extremely low contact resistance referred to as a contact spot can be formed at the portion where the Ag/Al phase and a p-type impurity diffusion layer of the crystalline silicon substrate make contact. There are preferably a large number of such contact spots in order to obtain a high-performance crystalline silicon solar cell. However, p-n junctions formed in the crystalline silicon substrate are destroyed if the contact spots end up being formed excessively deep. Thus, it is necessary to control the size of the contact spots formed.

The inventors of the present invention found that, by using an electrically conductive paste containing a prescribed added amount of an Al powder or Al compound powder having a prescribed particle diameter, the number and size of Ag/Al phase contact spots in the electrodes formed can be controlled, thereby leading to completion of the present invention. Namely, the inventors of the present invention found that, by using an electrically conductive paste containing a prescribed added amount of an Al powder or Al compound powder having a prescribed particle diameter, the electrically conductive paste is able to fire through an antireflective film in the firing process during electrode formation of a crystalline silicon solar cell, and that an electrode can be formed having low contact resistance without deeply eroding the p-type impurity diffusion layer, thereby leading to completion of the present invention. The present invention employs the following configurations to solve the aforementioned problems.

The present invention is an electrically conductive paste characterized by the following Configurations 1 to 8.

(Configuration 1)

Configuration 1 of the present invention is an electrically conductive paste for forming an electrode of a solar cell, wherein the electrically conductive paste contains (A) an electrically conductive powder, (B) an Al powder or Al compound powder having an average particle diameter of 0.5 μm to 3.5 μm, (C) glass frit and (D) an organic medium, and contains 0.5 parts by weight to 5 parts by weight of the Al powder or Al compound powder (B) based on 100 parts by weight of the electrically conductive powder (A).

According to Configuration 1 of the present invention, an electrically conductive paste can be provided that used to form a light incident side electrode of a crystalline silicon solar cell, the electrically conductive paste being able to fire through an antireflective film during firing and form an electrode having low contact resistance on a p-type impurity diffusion layer.

(Configuration 2)

Configuration 2 of the present invention is the electrically conductive paste of Configuration 1, wherein the electrically conductive powder (A) contains at least one of Ag powder, Cu powder, Ni powder and a mixture thereof.

Silver (Ag) is a substance that demonstrates high electrical conductivity, and can be preferably used as an electrode material of a crystalline silicon solar cell. In addition, although silver is expensive, by using a comparatively inexpensive Cu powder and/or Ni powder, an electrode of a crystalline silicon solar cell can be formed at low cost.

(Configuration 3)

Configuration 3 of the present invention is the electrically conductive paste of Configuration 1 or 2, wherein the Al compound powder (B) is an alloy powder containing Al.

According to Configuration 3 of the present invention, as a result of the Al compound powder (B) of the electrically conductive paste of the present invention being an alloy powder that contains Al, an electrode having low contact resistance can be formed more reliably on the p-type impurity diffusion layer.

(Configuration 4)

Configuration 4 of the present invention is the electrically conductive paste of any of Configurations 1 to 3, wherein the glass frit (C) comprises at least one material selected from the group consisting of lead oxide (MO), boron oxide (B₂O₃), silicon oxide (SiO₂), zinc oxide (ZnO), bismuth oxide (Bi₂O₃) and aluminum oxide (Al₂O₃).

According to Configuration 4 of the present invention, as a result of the glass frit contained in the electrically conductive paste of the present invention containing a prescribed oxide, the electrically conductive paste is able to more reliably fire through the antireflective film during firing thereof.

(Configuration 5)

Configuration 5 of the present invention is the electrically conductive paste of any of Configurations 1 to 4, wherein the organic vehicle (D) comprises at least one material selected from the group consisting of ethyl cellulose, rosin ester, butyral, acrylic and organic solvent.

According to Configuration 5 of the present invention, as a result of the organic vehicle (D) contained in the electrically conductive paste of the present invention being a prescribed substance, screen printing of an electrode pattern using the electrically conductive paste of the present invention can be carried out more easily.

(Configuration 6)

Configuration 6 of the present invention is the electrically conductive paste of any of Configurations 1 to 5, wherein the electrically conductive paste further comprises at least one material selected from the group consisting of titanium resinate, titanium oxide, cerium oxide, silicon nitride, copper-manganese-tin, aluminosilicate and aluminum silicate.

According to Configuration 6 of the present invention, as a result of the electrically conductive paste of the present invention further containing at least one material selected from the group consisting of titanium resinate, titanium oxide, cerium oxide, silicon nitride, copper-manganese-tin, aluminosilicate and aluminum silicate, fire-through of the antireflective film and the formation of an electrode having low contact resistance on the p-type impurity diffusion layer can be carried out more reliably.

(Configuration 7)

Configuration 7 of the present invention is the electrically conductive paste of any of Configurations 1 to 6, which is an electrically conductive paste for forming an electrode on p-type semiconductor layer of a solar cell.

The electrically conductive paste of the present invention can be particularly preferably used to form an electrode on a p-type semiconductor layer of a solar cell.

(Configuration 8)

Configuration 8 of the present invention is the electrically conductive paste of any of Configurations 1 to 7, which is an electrically conductive paste for forming an electrode on a p-type emitter layer of a crystalline silicon solar cell, wherein the crystalline silicon solar cell comprises an n-type crystalline silicon substrate and a p-type emitter layer formed on one of the main surfaces of the n-type crystalline silicon substrate.

The electrically conductive paste of the present invention can be particularly preferably used to form an electrode on a p-type emitter layer of a crystalline silicon solar cell.

(Configuration 9)

Configuration 9 of the present invention is a solar cell having at least a portion of the electrodes formed using the electrically conductive paste of any of Configurations 1 to 8.

According to Configuration 9 of the present invention, a high-performance crystalline silicon solar cell can be provided that has an electrode having low contact resistance on a p-type impurity diffusion layer.

### Effects of the Invention

According to the present invention, an electrically conductive paste can be provided that used to form an electrode of a crystalline silicon solar cell, the electrically conductive paste being able to fire through an antireflective film during firing and form an electrode having low contact resistance on a p-type semiconductor layer.

In addition, according to the present invention, a high-performance crystalline silicon solar cell can be provided that has an electrode having low contact resistance on a p-type semiconductor layer.

### BRIEF DESCRIPTION OF THE DRAWINGS

FIG. 1 is an example of a schematic diagram of an ordinary crystalline silicon solar cell.

FIG. 2 is an example of a schematic diagram of an electrode pattern of an ordinary crystalline silicon solar cell.

FIG. 3 is an example of a cross-sectional schematic diagram of a bifacial crystalline silicon solar cell.

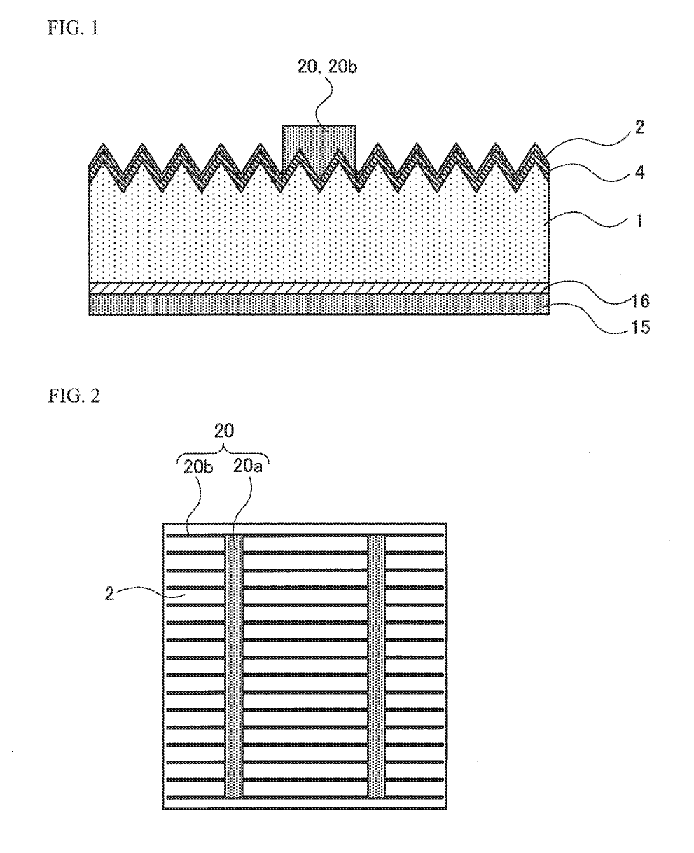

### MODE FOR CARRYING OUT THE INVENTION

in the present description, “crystalline silicon” includes single crystalline silicon and polycrystalline silicon. In addition, a “crystalline silicon substrate” refers to a material formed into a shape suitable for the formation of a device, such as forming crystalline silicon into the shape of a flat plate for forming an electrical device, electronic device or other semiconductor device. Any method may be used to produce the crystalline silicon. For example, the Czochralski method can be used in the case of single crystalline silicon, while the casting method can be used in the case of polycrystalline silicon. In addition, polycrystalline silicon fabricated according to other production methods such as the ribbon pulling method or polycrystalline silicon formed on a heterogeneous material such as glass can also be used as a crystalline silicon substrate. In addition, a “crystalline silicon solar cell” refers to a solar cell fabricated using a crystalline silicon substrate.

In the present description, “glass frit” refers to that having for the primary material thereof a plurality of types of oxides such as metal oxides, and that in the form of glass-like particles is used most commonly.

The present invention is an electrically conductive paste for forming an electrode of a solar cell. The electrically conductive paste of the present invention contains (A) an electrically conductive powder, (B) Al powder or Al compound powder, (C) glass flit and (D) an organic medium. The average particle diameter of the Al powder or Al compound powder (B) contained in the electrically conductive paste of the present invention is 0.5 μm to 3.5 μm. The content of the Al powder or Al compound powder (B) is 0.5 parts by weight to 5 parts by weight based on 100 parts by weight of the electrically conductive powder (A). Use of the electrically conductive paste of the present invention enables the formation of an electrode having low contact resistance on a p-type semiconductor layer (and particularly, a p-type impurity diffusion layer) since the electrically conductive paste is able to fire through an antireflective film.

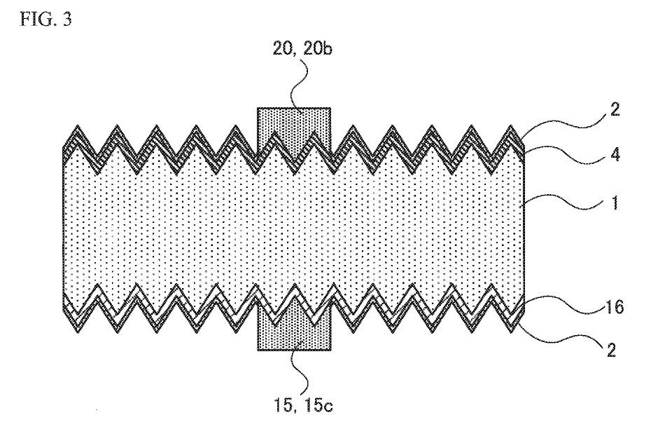

The following provides an explanation of the electrically conductive paste of the present invention using as an example the case of forming a light incident side electrode (surface electrode) 20 of a crystalline silicon solar cell using an n-type crystalline silicon substrate 1. In the case of this crystalline silicon solar cell, the impurity diffusion layer 4 formed on the light incident side surface is a p-type impurity diffusion layer 4. An antireflective film 2 is formed on the surface of the p-type impurity diffusion layer 4 as shown in FIG. 3.

As shown in FIG. 2, bus bar electrodes (light incident side bus bar electrodes) 20a and finger electrodes 20b are arranged as light incident side electrodes 20 on the light incident side surface of a crystalline silicon solar cell.

In the example shown in FIG. 2, carriers generated by incident light that has entered the crystalline silicon solar cell are gathered in the finger electrodes 20b via the p-type diffusion layer 4. Thus, contact resistance between the finger electrodes 20b and the p-type diffusion layer 4 is required to be low. Moreover, the finger electrodes 20b are formed by printing a prescribed electrically conductive paste on the antireflective film 2 and allowing the electrically conductive paste to fire through the antireflective film 2 during firing. Thus, the electrically conductive paste for forming the finger electrodes 20b is required to have performance that allows fire-through of the antirefiective film 2. The electrically conductive film of the present invention can be preferably used to form the finger electrodes 20b of a crystalline silicon solar cell using the n-type crystalline silicon substrate 1.

The following provides a detailed explanation of the electrically conductive paste of the present invention.

The electrically conductive paste of the present invention contains an electrically conductive powder (A), Al powder or Al compound powder (B), glass frit (C) and an organic medium (D).

An electrically conductive material such as a metal material can be used for the main component of the electrically conductive powder contained in the electrically conductive paste of the present invention. In the electrically conductive paste of the present invention, the electrically conductive powder (A) can contain at least one of silver (Ag) powder, copper (Cu) powder, nickel (Ni) powder and a mixture (alloy) thereof. Furthermore, silver powder is preferably used for the electrically conductive powder. In addition, the electrically conductive paste of the present invention can contain copper (Cu) powder and nickel (Ni) powder within a range that does not impair the performance of solar cell electrodes. In addition, the electrically conductive paste of the present invention can contain powders of other metals such as gold, zinc or tin. The aforementioned metal can be used in the form of a powder of the metal alone or can be used in the form of an alloy powder. The electrically conductive powder contained in the electrically conductive paste of the present invention preferably composed of silver from the viewpoint of obtaining low electrical resistance and high reliability.

There are no particular limitations on the shape or dimension (also referred to as particle diameter) of the particles of the electrically conductive powder. Particles in the shape of, for example, spheres or scales can be used for the shape of the particles. Particle dimension refers to the dimension of the portion of a single particle having the longest length. The particle dimension of the electrically conductive powder is preferably 0.5 μm to 20 μm, more preferably 0.1 μm to 10 μm, and even more preferably 0.5 μm to 3 μm from the viewpoint of ease of manipulation. In the case the particle dimension exceeds the aforementioned ranges, problems occur such as clogging during screen printing. In addition, in the case the particle dimension is below the aforementioned ranges, the particles become excessively sintered during firing, thereby preventing an electrode from being adequately formed.

In general, since the dimensions of microparticles have a certain distribution, it is not necessary for all particles to have the aforementioned dimension, but rather the particle dimension of 50% of the integrated value of all particles (D50) is preferably within the aforementioned particle dimension ranges. In addition, the average value of particle dimension (average particle diameter) may also be within the aforementioned ranges. This applies similarly to particles other than those of the electrically conductive powder described in the present description. Furthermore, average particle diameter can be determined by measuring particle size distribution according to the Microtrac method (laser diffraction/scattering) and obtaining the D50 value from the results of particle size distribution measurement.

In addition, the size of the electrically conductive powder can also be expressed as the BET value (BET specific surface area). The BET value of the electrically conductive powder is preferably 0.1 m²/g to 5 m²/g and more preferably 0.2 m²/g to 2 m²/g.

The electrically conductive paste of the present invention contains (B) powder or Al compound powder.

When an electrode is formed by firing an electrically conductive paste containing an electrically conductive powder consisting of Ag powder, glass frit and Al powder or Al compound powder, the electrically conductive paste is able to form an Ag/Al phase in the electrode. An Ag/Al phase in an electrode is known to contribute to the obtaining of low contact resistance with respect to a p-type semiconductor. The inventors of the present invention found that the amount of the Ag/Al phase present in an electrode has a considerable effect on contact resistance between the electrode and a p-type semiconductor. In addition, the size of the Ag/AI phase was found to be largely dependent on the particle diameter of the particles of the Al powder or Al compound powder. In order to obtain low contact resistance of the light incident side electrode, or in other words, obtain a crystalline silicon solar cell having high conversion efficiency, the average particle diameter of the Al powder or Al compound powder is preferably 0.5 μm to 3.5 μm and more preferably 0.5 μm to 3 μm. In addition, the average particle diameter of the Al powder or Al compound powder is preferably smaller in comparison with that of the prior art, and can be less than 3 μm.

Component (B) contained in the electrically conductive paste of the present invention is preferably an Al powder. In addition, in the case component (B) is an Al compound powder, there are no particular limitations on the type thereof. However, in order to form an electrode having low contact resistance on a p-type impurity diffusion layer more reliably, the Al compound powder contained in the electrically conductive paste of the present invention is preferably an alloy powder containing Al. An alloy containing Al and Zn, for example, can be used as an alloy that contains Al. In addition, an alloy of Al and one or more materials selected from Cu, Ni, Au, Zn and Sn can be used.

In the electrically conductive paste of the present invention, the content of the Al powder or Al compound powder (B) is 0.5 parts by weight to 5 parts by weight and preferably 0.5 parts by weight to 4 parts by weight based on 100 parts by weight of the electrically conductive powder (A). By making the added amount of the Al powder or Al compound powder (B) to be within a prescribed range, an Ag/Al phase can be formed reliably and an electrode having low contact resistance can be formed.

Next, an explanation is provided of the glass frit contained in the electrically conductive paste of the present invention.

In the electrically conductive paste of the present invention, the glass fit (C) is preferably glass frit containing at least one material selected from the group consisting of lead oxide (PhO), boron oxide (B₂O₃), silicon oxide (SiO₂), zinc oxide (ZnO), bismuth oxide (Bi₂O₃) and aluminum oxide (Al₂O₃). The content ratio of the glass frit (C) in the electrically conductive paste is 0.1 part by weight to 20 parts by weight, preferably 1 part by weight to 15 parts by weight, and more preferably 2 parts by weight to 10 parts by weight of glass frit based on 100 parts by weight of the electrically conductive powder. As a result of containing a prescribed amount of glass frit relative to the content of the electrically conductive powder, fire-through of the antireflective film can be carried out more reliably while maintaining electrical continuity of the electrode by the electrically conductive powder.

The glass frit contained in the electrically conductive paste of the present invention preferably contains lead oxide (PbO), silicon oxide (SiO₂), zinc oxide (ZnO), bismuth oxide (Bi₂O₃), boron oxide (B₂O₃) and aluminum oxide (Al₂O₃). As a result of the glass frit containing these oxides, fire-through of the antireflective film is superior. In addition, the softening point of the glass fit can be adjusted by adjusting the contents of these oxides. Consequently, fluidity of the glass frit during firing of the electrically conductive paste can be adjusted, and a crystalline silicon solar cell having favorable performance can be obtained in the case of using an electrically conductive paste to form an electrode for a crystalline silicon solar cell.

The total content of PbO in 100 parts by weight of the prescribed glass frit in the electrically conductive paste of the present invention is preferably 50 parts by weight to 97 parts by weight, more preferably 60 parts by weight to 92 parts by weight, and even more preferably 70 parts by weight to 90 parts by weight. A crystalline silicon solar cell having more favorable performance can be obtained in the case of using an electrically conductive paste having glass frit containing a prescribed amount of PbO to form an electrode for a crystalline silicon solar cell.

There are no particular limitations on the shape of the glass fit particles, and spherical or irregularly shaped particles can be used. In addition, there are also no particular limitations on the particle dimension, and the average value of particle diameter (D50) is preferably within the range of 0.1 μm to 10 μm and more preferably within the range of 0.5 μm to 5 μm from the viewpoint of ease of manipulation and the like.

One type of glass frit particles can be used that respectively contain prescribed amounts of the required plurality of glass frit components. In addition, particles composed of glass fit composed of a single component can also be used as particles having different required plurality of glass frit for each component. In addition, a plurality of types of particles having different compositions of glass frit components can be used in combination.

In order to obtain a suitable softening function of the glass frit when firing the electrically conductive paste of the present invention, the softening point of the glass frit is preferably 200° C. to 700° C., more preferably 220° C. to 650° C., and even more preferably 220° C. to 600° C.

The electrically conductive paste of the present invention contains an organic vehicle (D). An organic binder and solvent can be contained for the organic vehicle. The organic binder and solvent fulfill the role of adjusting viscosity of the electrically conductive paste and there are no particular limitations thereon. The organic binder can also be used by dissolving in the solvent.

The organic vehicle (D) of the electrically conductive paste of the present invention preferably contains at least one material selected from the group consisting of ethyl cellulose, rosin ester, butyral, acrylic and organic solvent. The organic vehicle is obtained by dissolving a resin component used for the organic binder in an organic solvent. An organic binder can be used for the organic binder that is selected from a cellulose-based resin such as ethyl cellulose, an acrylic resin, a butyral resin and an alkyd resin.

More specifically, the organic binder can be selected from ethyl cellulose, ethyl hydroxyethyl cellulose, wood rosin, a mixture of ethyl cellulose and phenol resin, a polymethacrylate of a lower alcohol, a monobutyl ether of ethylene glycol monoacetate, hydroxypropyl cellulose (HPC), polyethylene glycol (PEG), polyethylene oxide (PEO), polyvinyl alcohol (PVA), polyvinylpyrrolidone (PVP), polyacrylic acid and derivatives thereof, polymethacrylate (PMA) and derivatives thereof polymethyl methacrylate (PMMA) and derivatives thereof and mixtures thereof. In addition, polymer resins other than those listed above can also be used for the organic binder.

The added amount of organic binder in the electrically conductive paste is normally 0.1 parts by weight to 30 parts by weight and preferably 0.2 parts by weight to 5 parts by weight based on 100 parts by weight of the electrically conductive powder.

One type of two or more types of solvents can be used that are selected from alcohols (such as terpineol, β-terpineol or β-terpineol), and esters (such as hydroxyl group-containing esters, 2,2,4-trimethyl-1,3-pentanediol monoisobutyrate and butyl carbitol acetate). The added amount of solvent is normally 0.5 parts by weight to 30 parts by weight and preferably 2 parts by weight to 25 parts by weight based on 100 parts by weight of the electrically conductive powder.

The electrically conductive paste of the present invention preferably further contains at least one material selected from the group consisting of titanium resinate, titanium oxide, cerium oxide, silicon nitride, copper-manganese-tin, aluminosilicate and aluminum silicate. As a result of the electrically conductive paste containing these components, fire-through of the antireflective film and the formation of an electrode having low contact resistance with respect to the p-type impurity diffusion layer can be carried out more reliably.

An additive selected from a plasticizer, antifoaming agent, dispersant, leveling agent, stabilizer and adhesion promoter can be further incorporated as an additive in the electrically conductive paste of the present invention as necessary. Among these, an additive selected from phthalic acid esters, glycolic acid esters, phosphoric acid esters, sebacic acid esters, adipic acid esters and citric acid esters can be used as a plasticizer.

The electrically conductive paste of the present invention can contain additives other than those listed above within a range that does not a detrimental effect on the properties of the resulting solar cell. However, in order to obtain a solar cell having favorable solar cell properties and favorable metal ribbon adhesive strength, the electrically conductive paste of the present invention is preferably an electrically conductive paste composed of an electrically conductive powder, the aforementioned prescribed glass frit and an organic vehicle.

Next, an explanation is provided of a method for producing the electrically conductive paste of the present invention. The electrically conductive paste of the present invention can be produced by adding and mixing an electrically conductive powder, glass frit and other additives as necessary with an organic binder and solvent followed by dispersing therein.

Mixing can be carried out with a planetary mixer, for example. In addition, dispersion can be carried out with a three-roll mill. Mixing and dispersion are not limited to these methods, but rather various known methods can be used.

Next, an explanation is provided of the crystalline silicon solar cell of the present invention. The present invention is a solar cell in which at least a portion of the electrodes are formed using the aforementioned electrically conductive paste of the present invention.

FIG. 3 shows a cross-sectional schematic diagram of a crystalline silicon solar cell having electrodes (light incident side electrodes 20 and a back side electrode 15) on both the light incident side and back side. The crystalline silicon solar cell shown in FIG. 3 has light incident side electrodes 20 formed on the light incident side, a reflective film 2, a p-type impurity diffusion layer (p-type silicon layer) 4, an n-type crystalline silicon substrate 1, and a back side electrode 15. In addition, FIG. 2 shows an example of a schematic diagram of an electrode pattern of a typical crystalline silicon solar cell.

In the present description, electrodes for extracting current to the outside from the crystalline silicon solar cell in the form of the light incident side electrodes 20 and the back side electrode 15 may simply be collectively referred to as “electrodes”.

The electrically conductive paste of the present invention can be preferably used as an electrically conductive paste for forming an electrode on the p-type semiconductor layer (p-type emitter layer) of a solar cell in the manner of a crystalline silicon solar cell. Since the amount and size of the contact spot of the Ag/Al phase in the formed electrode can be suitably controlled, contact resistance between the p-type semiconductor layer and electrode can be lowered. In the case of the crystalline silicon solar cell shown in FIGS. 2 and 3, use of the electrically conductive paste of the present invention makes it possible to form finger electrodes 20b having low contact resistance on the light incident side surface.

In order to increase the incident light surface area for the crystalline silicon solar cell, the surface area occupied by the light incident side electrodes 20 on the light incident side surface is preferably as small as possible. Consequently, the finger electrodes 20b on the light incident side surface preferably have as narrow a width as possible. On the other hand, from the viewpoint of reducing electrical loss (ohmic loss), the width of the finger electrodes 20b is preferably as wide as possible. In addition, from the viewpoint of minimizing contact resistance between the finger electrodes 20b and the impurity diffusion layer 4 as well, the width of the finger electrodes 20b is preferably as wide as possible. In consideration of the above, the width of the finger electrodes 20b is 20 μm to 300 μm, preferably 35 μm to 200 μm, and more preferably 40 μm to 100 μm. Namely, the optimum interval and number of finger electrodes 20b can be determined by simulating solar cell operation so as to maximize conversion efficiency of the crystalline silicon solar cell.

As shown in FIG. 2, light incident side bus bar electrodes 20a are arranged on the light incident side surface of the crystalline silicon solar cell. The light incident side bus bar electrodes 20a are in electrical contact with the finger electrodes 20b. Interconnect metal ribbon and wires, for which the periphery thereof is covered with solder, are soldered to the light incident side bus bar electrodes 20a to extract current to the outside.

The electrically conductive paste of the present invention can be used for the electrically conductive paste for forming the light incident side bus bar electrodes 20 in the same manner as in the case of the finger electrodes 20b. However, an electrically conductive paste differing from the electrically conductive paste of the present invention can also be used as necessary.

The width of the light incident side bus bar electrodes 20a can be roughly the same as the width of the interconnect metal ribbon. In order to ensure that the light incident side bus bar electrodes 20a have low electrical resistance, the width of the light incident side bus bar electrodes 20a is preferably as wide as possible. On the other hand, the width of the light incident side bus bar electrodes 20a is preferably as narrow as possible in order to increase the incident surface area of light entering the light incident side surface. Consequently, the bus bar electrode width is 0.5 mm to 5 mm, preferably 0.5 mm to 3 mm and more preferably 0.7 mm to 2 mm. In addition, the number of bus bar electrodes can be determined according to the size of the crystalline silicon solar cell. More specifically, the number of bus bar electrodes can be made to be 1 to 5. Namely, the optimum number of bus bar electrodes can be determined by simulating solar cell operation so as to maximize conversion efficiency of the crystalline silicon solar cell. Furthermore, when producing a solar cell module, crystalline silicon solar cells are usually alternately connected in series by interconnect metal ribbon. Consequently, in the case back side bus bar electrodes 15a are present, the number of light incident side bus bar electrodes 20a and the number of back side bus bar electrodes 15a are preferably equal.

In addition, in the case of connecting crystalline silicon solar cells with metal wire instead of interconnect metal ribbon, the incident light surface area can be increased by making the size of the bus bar electrodes to be quite small. In such cases as well, the optimum number of wires and optimum shape of the bus bar electrodes can be determined so as to maximize conversion efficiency.

Furthermore, in the case the bifacial solar cell shown in FIG. 3 uses the p-type crystalline silicon substrate 1, and a p-type impurity diffusion layer is formed by using a back surface field layer 16 on the side opposite from the main light incident side surface, use of the electrically conductive paste of the present invention makes it possible to form the back side electrode 15 (back side finger electrodes 15c).

Next, an explanation is provided of a method for producing the crystalline silicon solar cell of the present invention.

The method for producing the crystalline silicon solar cell of the present invention includes a step for preparing a p-type or n-type crystalline silicon substrate 1. A boron (B)-doped p-type single crystalline silicon substrate or P (phosphorous)-doped n-type single crystalline silicon substrate can be used for the crystalline silicon substrate 1. In the following explanation, the explanation focuses primarily on an example in which an n-type crystalline silicon substrate 1 is used.

From the viewpoint of obtaining high conversion efficiency, a pyramid-shaped textured structure is preferably formed on the surface of the light incident side of the crystalline silicon substrate 1.

Next, the method for producing the crystalline silicon solar cell of the present invention includes a step for forming the impurity diffusion layer 4 of another conductivity type on one surface of the crystalline silicon substrate 1 prepared in the aforementioned step. In the case of, for example, using an n-type crystalline silicon substrate 1 for the crystalline silicon substrate 1, a p-type impurity diffusion layer 4 can be formed for the impurity diffusion layer 4. Furthermore, a p-type crystalline silicon substrate 1 can be used in the crystalline silicon solar cell of the present invention. In this case, an n-type impurity diffusion layer 4 is formed for the impurity diffusion layer 4.

When forming the impurity diffusion layer 4, the impurity diffusion layer 4 can be formed such that the sheet resistance of the impurity diffusion layer 4 is 40Ω/□ (ohm/square) to 200Ω/□ and preferably 45Ω/□ to 180Ω/□.

In addition, in the method for producing the crystalline silicon solar cell of the present invention, the depth at which the impurity diffusion layer 4 is formed can be 0.15 μm to 2.0 μm. Furthermore, the depth of the impurity diffusion layer 4 refers to the depth from the surface of the impurity diffusion layer 4 to the p-n junction. The depth of the p-n junction can be depth from the surface of the impurity diffusion layer 4 to the location where the impurity concentration of the impurity diffusion layer 4 is equal to the impurity concentration of the substrate.

Next, the method for producing the crystalline silicon solar cell of the present invention includes a step for forming an antireflective film 2 on the surface of the impurity diffusion layer 4 formed in the aforementioned step. The antireflective film 2 can be deposited by a method such as plasma-enhanced chemical vapor deposition (PECVD). The antireflective film 2 can be formed in the form of a silicon nitride film, silicon oxide film, aluminum oxide film or composite layer thereof. In addition to having an antireflective function with respect to incident light, since the antirefiective film 2 has the function of a surface passivation film, a high-performance crystalline silicon solar cell can be obtained.

Furthermore, in the case of a bifacial solar cell as shown in FIG. 3, an impurity diffusion layer is formed in the form of the prescribed back surface field layer 16. In the case of using an n-type crystalline silicon substrate, an n-type impurity diffusion layer is formed for the back surface field layer 16. In addition, in the case of using a p-type crystalline silicon substrate 1, a p-type impurity diffusion layer is formed for the back surface field layer 16. Subsequently, the antirefiective film 2 is also formed on the back side in the same manner as that on the light incident side surface.

The method for producing the crystalline silicon solar cell of the present invention includes a step for printing an electrically conductive paste on the surface of the antirefiective film 2 and forming the light incident side electrodes 20 by firing. In addition, the method for producing the crystalline silicon solar cell of the present invention further includes a step for printing the electrically conductive paste on the other surface of the crystalline silicon substrate 1 and forming the back side electrode 15 by firing. More specifically, a pattern of the light incident side electrodes 20 printed using the prescribed electrically conductive paste is dried for several minutes (such as for 0.5 minutes to 5 minutes) at a temperature of about 100° C. to 150° C. Furthermore, in order to form the back side electrode 15 in continuation from printing and drying the pattern of the light incident side electrodes 20, the prescribed electrically conductive paste can be printed on the back side as well followed by drying. In the case an n-type crystalline silicon substrate 1 is used, a known electrically conductive paste for forming an electrode of a solar cell using silver for the electrically conductive powder can be used as the electrically conductive paste for forming the back side electrode 15.

Furthermore, in the case of a bifacial solar cell as shown in FIG. 3, electrodes in an electrode pattern (electrode pattern as shown in FIG. 2) similar to that of the light incident side electrodes 20 can be used for the back side electrode 15.

Subsequently, after drying the printed electrically conductive paste, the electrically conductive paste is fired under prescribed firing conditions in air using a tubular furnace or other firing furnace. Firing conditions preferably consist of air for the firing atmosphere and a faring temperature of 400° C. to 1000° C., more preferably 400° C. to 900° C., even more preferably 500° C. to 900° C. and particularly preferably 600° C. to 850° C. Firing is preferably carried out in a short period of time. The temperature profile (temperature vs. time curve) during firing is preferably in the form of a peak. For example, the in-out time of the firing furnace using the aforementioned temperatures for the peak temperature is such that firing is carried out for 10 seconds to 60 seconds and preferably for 20 seconds to 50 seconds.

During firing, the electrically conductive paste for forming the light incident side electrodes 20 and back side electrode 15 is preferably fired simultaneously to form both electrodes simultaneously. In this manner, by printing a prescribed electrically conductive paste onto the light incident side surface and back side and simultaneously firing the same, firing for electrode formation is only required to be carried out once. Consequently, the crystalline silicon solar cell can be produced at lower cost.

The crystalline silicon solar cell of the present invention can be produced in the manner described above.

In the method for producing the crystalline silicon solar cell of the present invention, the electrically conductive paste of the present invention is used to from the finger electrodes 20b on the light incident side surface. Consequently, the electrically conductive paste of the present invention is able to fire through the antireflective film 2 when firing the electrically conductive paste of the electrode pattern. In addition, by firing the electrically conductive paste of the present invention for forming the finger electrodes 20b on the light incident side surface, a contact spot for which size can be controlled is able to be formed at the interface between the finger electrodes 20b and the impurity diffusion layer 4. As a result, contact resistance between the finger electrodes 20b and the impurity diffusion layer 4 can be reduced.

A solar cell module can be obtained by electrically connecting crystalline silicon solar cells of the present invention obtained in the manner described above with interconnect metal ribbon or wire, and then and then laminating with a glass plate, sealing material and protective sheet and the like. A metal ribbon having the periphery thereof covered with solder (such a ribbon having copper for the material thereof) can be used for the interconnect metal ribbon. Solder mainly composed of tin, and more specifically, leaded solder, lead-free solder or other commercially available solder, can be used for the solder.

### EXAMPLES

Although the following provides a detailed explanation of the present invention through examples thereof, the present invention is not limited thereto.

<Materials and Formulation Ratios of Electrically Conductive Paste>

The compositions of electrically conductive pastes used to produce solar cells of the examples and comparative examples are as described below. Table 1 indicates the particle diameters and added amounts of Ag and Al particles, as well as the compositions and added amounts of glass fit, in the electrically conductive pastes of electrically conductive pastes “a” to “m” used in the examples and comparative examples.

(A) Electrically Conductive Powder

The Ag (100 parts by weight) shown in Table 1 was used. The shape of the Ag particles was spherical. The particle diameters of the Ag (average particle diameter D50) are shown in Table 1.

(B) Glass Frit

Glass fit formulated as shown in Table 1 was used. Table 1 indicates the added amounts of glass frit in the electrically conductive pastes “a” to “m” based on 100 parts by weight of the electrically conductive powder. Furthermore, the average particle diameter D50 of the glass frit was 2 μm.

(C) Organic Binder

Ethyl cellulose (0.4 parts by weight) was used for the organic binder.

(D) Solvent

Butyl carbitol acetate (3 parts by weight) was used for the solvent.

Next, the materials in the aforementioned prescribed formulation ratios were mixed with a planetary mixer and then dispersed with a three-roll mill followed by forming into a paste to prepare an electrically conductive paste.

<Production of Single Crystalline Silicon Solar Cell>

A bifacial single crystalline silicon solar cell was produced as exemplified in FIG. 3. A P (phosphorous)-doped n-type Si single crystalline substrate (substrate thickness: 200 μm) was used for the substrate.

First, after forming a silicon oxide layer on the aforementioned substrate to a thickness of about 20 μm by dry oxidation, the silicon oxide layer was etched with a solution consisting of a mixture of hydrogen fluoride, pure water and ammonium fluoride for removal of damage of the substrate surface. Moreover, heavy metals were washed off with an aqueous solution containing hydrochloric acid and hydrogen peroxide.

Next, a texture (in the shape of surface irregularities) was imparted to both sides of the substrate by dry etching. More specifically, pyramid-shaped textured structures (on the primary incident light surfaced side and back side) were formed with a wet etching solution (aqueous sodium hydroxide solution). Subsequently, the substrate was washed with an aqueous solution containing hydrochloric acid and hydrogen peroxide.

Next, boron was injected into one of the surfaces having a textured structure on the aforementioned substrate to form an n-type diffusion layer to a thickness of about 0.5 Sheet resistance of the p-type diffusion layer was 60 Ω/□.

In addition, phosphorous was injected into the other surface having a textured structure of the aforementioned substrate to form an n-type diffusion layer to a thickness of about 0.5 μm. Sheet resistance of the n-type diffusion layer was 20Ω/□. Injection of boron and phosphorous was carried out simultaneously by thermal diffusion.

Next, a thin oxide film layer of about 1 nm to 2 nm was formed on the surface of the substrate having the p-type diffusion layer formed thereon (light incident side surface) and the surface of the substrate having the n-type diffusion layer formed thereon (back side) followed by forming a silicon nitride thin film to a thickness of about 60 μm by plasma CVD using silane gas and ammonia gas. More specifically, a silicon nitride thin film (antirefiective film 2) having a film thickness of about 70 μm was formed by plasma CVD by glow discharge decomposition of a mixed gas having a ratio of NH₃/SiH₄ of 0.5 at a pressure of 1 Torr (133 Pa).

The electrically conductive pastes shown in Tables 2 to 6 were used for the electrically conductive pastes for forming an electrode on the surface of the substrate having a p-type diffusion layer formed thereon (light incident side surface) of the single crystalline silicon solar cells in the examples, comparative examples and reference examples.

Printing of electrically conductive paste was carried out by screen printing. An electrode pattern composed of light incident side bus bar electrodes 20a having a width of 1.5 mm and light incident side finger electrodes 20a having a width of 60 μm was printed to a film thickness of about 20 μm on the antireflective film 2 of the aforementioned substrate followed by drying for about 1 minute at 150° C.

A commercially available Ag paste was printed by screen printing for use as the back side electrode 15 (electrode on the surface having the n-type diffusion layer formed thereon). Furthermore, the electrode pattern of the back side electrode 15 employed the same electrode pattern as the light incident side electrodes 20. Subsequently, the printed Ag paste was dried for about 60 minutes at 150° C. The film thickness of the electrically conductive paste for the back side electrode 15 after drying was about 20 μm. Subsequently, both sides were simultaneously fired in a firing furnace in-out time of 50 seconds and peak temperature of 720° C. using the CDF7210 belt furnace (firing furnace) manufactured by Despatch Industries, Inc. Single crystalline silicon solar cells were produced in the manner described above.

Electrical characteristics of the single crystalline silicon solar cells were measured in the manner indicated below. Namely, current-voltage characteristics of the trial-produced solar cells were measured under conditions of 25° C. and AM 1.5 while irradiating with light generated by a solar simulator (energy density: 100 mW/cm²) using the SS-150XIL solar simulator manufactured by EKO Instruments Co., Ltd., followed by calculating conversion efficiency from the measurement results. Furthermore, two single crystalline silicon solar cells were produced under the same production conditions and measured values were determined by taking the average value of the two.

### Examples 1 to 7 and Comparative Examples 1 to 4

The single crystalline silicon solar cells of Examples 1 to 7 and Comparative Examples 1 to 4 were produced as shown in Table 2 using the electrically conductive pastes shown in Table 1. Furthermore, the particle diameters and added amounts of Al particles contained in the electrically conductive pastes are shown in Table 2 for reference purposes. In addition, the results of measuring conversion efficiency of the single crystalline silicon solar cells of Examples 1 to 7 and Comparative Examples 1 to 4 are shown in Table 2.

As is clear from the measurement results for conversion efficiency shown in Table 2, the conversion efficiencies of the single crystalline silicon solar cells of Examples 1 to 7 of the present invention were all 19% or higher. In contrast, the conversion efficiencies of the single crystalline silicon solar cells of Comparative Examples 1 to 4 were all below 19%. Thus, the single crystalline silicon solar cells of Examples 1 to 7 of the present invention can be said to demonstrate high performance in comparison with the single crystalline silicon solar cells of Comparative Examples 1 to 4.

More specifically, as shown in Table 2, when Comparative Examples 1 and 2 are compared with Examples 1 to 4, the conversion efficiency of the solar cell became higher in the case the particle diameter of the Al powder in the electrically conductive paste was 0.5 μm to 3.5 μm. Among these, particularly high conversion efficiency was able to be obtained in the case the particle diameter of the Al powder in the electrically conductive paste was 0.5 μM to 3.0 μm. In addition, when Comparative Examples 3 and 4 are compared with Examples 2 and 5 to 7, high conversion efficiency was able to be obtained in the case the added amount of Al powder in the electrically conductive paste was 0.5 parts by weight to 5 parts by weight. Among these, particularly high conversion efficiency was able to be obtained in the case the added amount of Al powder in the electrically conductive paste was 0.5 parts by weight to 4 parts by weight.

Table 3 indicates the conversion efficiencies of single crystalline silicon solar cells of Reference Examples 1 and 2. Furthermore, the single crystalline silicon solar cells of Reference Examples 1 and 2 are single crystalline silicon solar cells that used the electrically conductive pastes “c” and “d” used in Examples 2 and 3 for the back side electrode 15 (electrode on the surface having the n-type diffusion layer formed thereon). Furthermore, formation of the light incident side electrodes on the surface of the substrate having the p-type diffusion layer formed thereon (light incident side surface) was also carried out using the same electrically conductive pastes “c” and “d”.

As is clear from the measurement results for conversion efficiency shown in Table 3, conversion efficiencies of the single crystalline silicon solar cells of Reference Examples 1 and 2, in which the electrically conductive pastes “c” and “d” used in Examples 2 and 3 were also used for the electrodes on the surface having the n-type diffusion layer formed thereon, were all below 19%. Thus, the electrically conductive paste of the present invention can be said to be able to be preferably used as an electrode on a surface having a p-type diffusion layer formed thereon in comparison with an n-type diffusion layer.

Table 4 shows the conversion efficiency of the single crystalline silicon solar cell of Example 8. Furthermore, when producing the single crystalline silicon solar cell of Example 8, an electrically conductive paste containing an Al compound (alloy of Al and Zn having a compounding ratio of Al:Zn=50:50) was used instead of the Al powder of the electrically conductive paste used in Example 2. The measurement results for Example 2 are also shown in Table 4 for reference purposes.

As is clear from the measurement results for conversion efficiency shown in Table 4, a high conversion efficiency of 19.8% was able to be obtained even in the case of the single crystalline silicon solar cell of Example 8 that was produced using an electrically conductive paste containing an Al compound instead of Al powder.

Table 5 indicates the conversion efficiency of the single crystalline silicon solar cell of Example 9 that was produced using electrically conductive paste “1”. Furthermore, when compared with electrically conductive paste “c” used in Example 2, electrically conductive paste “1” differs only in the particle diameter of the Ag powder. The measurement results for Example 2 are also shown in Table 5 for reference purposes.

As is clear from the measurement results for conversion efficiency shown in Table 5, a single crystalline silicon solar cell having high conversion efficiency of 20.1% was able to be obtained even in the case of using an electrically conductive paste incorporating Ag particles having a particle diameter of 1.5 μm, Thus, a single crystalline silicon solar cell having high conversion efficiency can be said to be able to be obtained when at least the particle diameter of the Ag particles in the electrically conductive paste is within the range of 1.5 μm to 2.0 μm.

Table 6 indicates the conversion efficiency of the single crystalline silicon solar cell of Example 10 that was produced using electrically conductive paste “m”, Furthermore, when compared with electrically conductive paste “c” used in Example 2, electrically conductive paste “m” differs only in the composition of the glass frit. Although the glass frit of electrically conductive paste “m” is incorporated with lead oxide (PbO), silicon oxide (SiO₂), zinc oxide (ZnO), bismuth oxide (Bi₂O₃) and aluminum oxide (Al₂O₃), it does not incorporated boron oxide (B₂O₃). The measurement results for Example 2 are also shown in Table 6 for reference purposes.

As is clear from the measurement results for conversion efficiency shown in Table 6, a single crystalline silicon solar cell having high conversion efficiency of 20.2% was able to be obtained even in the case of using an electrically conductive paste incorporated with glass frit having a different composition.

TABLE 1

| | | Ag amount | | Al amount | Glass frit | |
|---|---|---|---|---|---|---|
| Electrically | Ag particle | added | Al particle | added | added amount | |
| conductive | diameter | (parts by | diameter | (parts by | (parts by | Glass frit composition (numbers indicated before |
| paste No. | (μm) | weight) | (μm) | weight) | weight) | oxide name indicate percent by weight) |
| a | 2 | 100 | 0.3 | 1.5 | 5 | 60PbO—25B₂O₃—5SiO₂—5ZnO—3Bi₂O₃—2Al₂O₃ |
| b | 2 | 100 | 0.5 | 1.5 | 5 | |
| c | 2 | 100 | 1 | 1.5 | 5 | |
| d | 2 | 100 | 3 | 1.5 | 5 | |
| e | 2 | 100 | 3.5 | 1.5 | 5 | |
| f | 2 | 100 | 4 | 1.5 | 5 | |
| g | 2 | 100 | 1 | 0.3 | 5 | |
| h | 2 | 100 | 1 | 0.5 | 5 | |
| i | 2 | 100 | 1 | 4 | 5 | |
| j | 2 | 100 | 1 | 5 | 5 | |
| k | 2 | 100 | 1 | 6 | 5 | |
| l | 1.5 | 100 | 1 | 1.5 | 5 | |
| m | 2 | 100 | 1 | 1.5 | 5 | 55PbO—30SiO₂—10ZnO—3Bi₂O₃—2Al₂O₃ |

TABLE 2

| | | Al powder | | | |
|---|---|---|---|---|---|
| | Semiconduc- | Particle | Amount | Elec- | Conver- |
| | tor layer | diam- | added | trically | sion |
| | contacting | eter | (parts by | conductive | efficiency |
| | electrode | (μm) | weight) | paste No. | (%) |
| Comparative | p-type | 0.3 | 1.5 | a | 18.7 |
| Example 1 | | | | | |
| Example 1 | p-type | 0.5 | 1.5 | b | 19.8 |
| Example 2 | p-type | 1 | 1.5 | c | 20.3 |
| Example 3 | p-type | 3 | 1.5 | d | 20.0 |
| Example 4 | p-type | 3.5 | 1.5 | e | 19.3 |
| Comparative | p-type | 4 | 1.5 | f | 17.5 |
| Example 2 | | | | | |
| Comparative | p-type | 1 | 0.3 | g | 18.7 |
| Example 3 | | | | | |
| Example 5 | p-type | 1 | 0.5 | h | 19.8 |
| Example 6 | p-type | 1 | 4 | i | 19.8 |
| Example 7 | p-type | 1 | 5 | j | 19.3 |
| Comparative | p-type | 1 | 6 | k | 17.6 |
| Example 4 | | | | | |

TABLE 3

| | | Al powder | | | |
|---|---|---|---|---|---|
| | Semiconduc- | Particle | Amount | Elec- | Conver- |
| | tor layer | diam- | added | trically | sion |
| | contacting | eter | (parts by | conductive | efficiency |
| | electrode | (μm) | weight) | paste No. | (%) |
| Reference | n-type | 1 | 1.5 | c | 18.1 |
| Example 1 | | | | | |
| Reference | | 3 | 1.5 | d | 17.5 |
| Example 2 | | | | | |

TABLE 4

| | | Al powder/Al compound in | | | |
|---|---|---|---|---|---|
| | | electrically conductive paste | | | |
| | Semiconduc- | Particle | Amount | | Conver- |
| | tor layer | diam- | added | | sion ef- |
| | contacting | eter | (parts by | | ficiency |
| | electrode | (μm) | weight) | Remarks | (%) |
| (Example 2) | p-type | 1 | 1.5 | Al powder | 20.3 |
| Example 8 | | 1 | 3 | Al | 19.8 |
| | | | | compound | |
| | | | | (Al:Zn = | |
| | | | | 50:50 alloy) | |

TABLE 5

| | | Ag powder | Al powder | | | |
|---|---|---|---|---|---|---|
| | Semiconductor | Particle | Particle | Amount added | Electrically | Conversion |
| | layer contacting | diameter | diameter | (parts by | conductive | efficiency |
| | electrode | (μm) | (μm) | weight) | paste No. | (%) |
| (Example 2) | p-type | 2 | 1 | 1.5 | c | 20.3 |
| Example 9 | | 1.5 | 1 | 1.5 | l | 20.1 |

TABLE 6

| | | | Al powder | | | |
|---|---|---|---|---|---|---|
| | Semiconductor | | Particle | Amount added | Electrically | Conversion |
| | layer contacting | | diameter | (parts by | conductive | efficiency |
| | electrode | Glass frit composition | (μm) | weight) | paste No | (%) |
| (Example 2) | p-type | 60PbO—25B₂O₃—5SiO₂—5ZnO—3Bi₂O₃—2Al₂O₃ | 1 | 1.5 | c | 20.3 |
| Example 10 | | 55PbO—30SiO₂—10ZnO—3Bi₂O₃—2Al₂O₃ | 1 | 1.5 | m | 20.2 |

1 Crystalline silicon substrate
2 Antireflective film
4 Impurity diffusion layer
15 Back side electrode
15c Back side finger electrodes
16 Back surface field layer (back side impurity diffusion layer)
20 Light incident side electrodes (surface electrodes)
20a. Light incident side bus bar electrodes
20b Light incident side finger electrodes

1. An electrically conductive paste for forming an electrode of a solar cell, wherein the electrically conductive paste comprises:
(A) an electrically conductive powder, (B) an Al powder or Al compound powder having an average particle diameter of 0.5 μm to 3.5 μm, (C) a glass frit and (D) an organic vehicle,
wherein 0.5 parts by weight to 5 parts by weight of the Al powder or Al compound powder (B) based on 100 parts by weight of the electrically conductive powder (A).

2. The electrically conductive paste according to claim 1, wherein the electrically conductive powder (A) contains at least one of Ag powder, Cu powder, Ni powder and a mixture thereof.

3. The electrically conductive paste according to claim 1, wherein the Al compound powder (B) is an alloy powder containing Al.

4. The electrically conductive paste according to claim 1, wherein the glass frit (C) comprises at least one material selected from the group consisting of lead oxide (PbO), boron oxide (B₂O₃), silicon oxide (SiO₂), zinc oxide (ZnO), bismuth oxide (Bi₂O₃) and aluminum oxide (Al₂O₃).

5. The electrically conductive paste according to claim 1, wherein the organic vehicle (D) comprises at least one material selected from the group consisting of ethyl cellulose, rosin ester, butyral, acrylic and organic solvent.

6. The electrically conductive paste according to claim 1, wherein the electrically conductive paste further comprises at least one material selected from the group consisting of titanium resinate, titanium oxide, cerium oxide, silicon nitride, copper-manganese-tin, aluminosilicate and aluminum silicate.

7. The electrically conductive paste according to claim 1, which is an electrically conductive paste for forming an electrode on a p-type semiconductor layer of a solar cell.

8. The electrically conductive paste according to claim 1, which is an electrically conductive paste for forming an electrode on a p-type emitter layer of a crystalline silicon solar cell, and wherein the crystalline silicon solar cell comprises an n-type crystalline silicon substrate and a p-type emitter layer formed on one of the main surfaces of the n-type crystalline silicon substrate.

9. A solar cell comprising electrodes, wherein at least a portion of the electrodes are formed from the electrically conductive paste according to claim 1.
